(19) United States
(12) Patent Application Publication
(10) Pub. No.: US 2025/0300117 A1
(43) Pub. Date: Sep. 25, 2025

(54) SEMICONDUCTOR PACKAGE STRUCTURES BASED ON CHIP BACK WAFER BONDING

(71) Applicant: Yangtze Memory Technologies Co., Ltd., Wuhan (CN)

(72) Inventors: Min WEN, Wuhan (CN); Zhen PAN, Wuhan (CN); Shu WU, Wuhan (CN)

(21) Appl. No.: 18/638,607

(22) Filed: Apr. 17, 2024

(30) Foreign Application Priority Data
Mar. 20, 2024 (CN) 202410328031.3

(51) Int. Cl. H01L 23/00; H01L 23/31; H01L 23/528; H01L 23/544; H01L 25/00; H01L 25/18

(52) U.S. Cl. CPC H01L 24/24; H01L 23/3107; H01L 23/5283; H01L 23/544; H01L 24/32; H01L 24/73; H01L 25/18; H01L 25/50; H01L 2223/54426; H01L 2224/24137; H01L 2224/32225; H01L 2224/73267; H01L 2924/1431

(57) ABSTRACT

The present disclosure relates to semiconductor package structures and fabrication methods thereof. An example method includes providing a first semiconductor structure, a second semiconductor structure, and a carrier structure. The method further includes bonding the first semiconductor structure and the second semiconductor structure to a surface of the carrier structure, where the first semiconductor structure and the second semiconductor structure are disposed at different positions on the surface.

### CROSS-REFERENCE TO RELATED APPLICATIONS

This application claims priority to Chinese Patent Application No. 202410328031.3, filed on Mar. 20, 2024, which is hereby incorporated by reference in its entirety.

### TECHNICAL FIELD

The present disclosure relates to semiconductor package structures and fabrication methods thereof.

### BACKGROUND

Semiconductor packaging refers to the process of enclosing and protecting semiconductor dies or chips after they have been manufactured on semiconductor wafers. This packaging provides a means to connect the dies or chips to a device that they will power, such as a computer, smartphone, or countless other electronic gadgets. The choice of packaging technique is based on several factors including the intended application, power consumption, heat generation, and desired footprint. As technology continues to advance, smaller, more efficient, and more functional packaging solutions are desirable.

### SUMMARY

The present disclosure relates to semiconductor package structures and fabrication methods thereof.

One aspect of the present disclosure features a method. The method includes providing a first semiconductor structure, a second semiconductor structure, and a carrier structure. The method further includes bonding the first semiconductor structure and the second semiconductor structure to a surface of the carrier structure, where the first semiconductor structure and the second semiconductor structure are disposed at different positions on the surface.

In some implementations, the method further includes forming a redistribution layer.

In some implementations, the first semiconductor structure is different from the second semiconductor structure.

In some implementations, the first semiconductor structure includes a logic die, the second semiconductor structure includes a memory die, and the carrier structure includes a carrier wafer.

In some implementations, the method further includes forming a first mark on a surface of the first semiconductor structure, forming a second mark on a surface of the second semiconductor structure, and forming a third mark and a fourth mark on the surface of the carrier structure. A first position of the first semiconductor structure on the surface is determined based on the first mark and the third mark. A second position of the second semiconductor structure on the surface is determined based on the second mark and the fourth mark.

In some implementations, the first semiconductor structure and the second semiconductor structure are formed based on different levels of technology nodes. The method further includes forming an insulating structure over and surrounding the first semiconductor structure and the second semiconductor structure. The method further includes forming an interconnect layer over the insulating structure, wherein the first semiconductor structure and the second semiconductor structure are coupled through the interconnect layer.

Another aspect of the present disclosure features a semiconductor device. The semiconductor device includes a first semiconductor structure and a second semiconductor structure disposed at different positions on a surface. The semiconductor device further includes an interconnect layer over the first semiconductor structure and the second semiconductor structure, where the first semiconductor structure and the second semiconductor structure are coupled through the interconnect layer. The semiconductor device further includes a redistribution layer over the interconnect layer, where the redistribution layer is coupled to the interconnect layer.

In some implementations, the redistribution layer includes a conductive pad coupled to the interconnect layer.

In some implementations, the semiconductor device further includes an insulating structure isolating the first semiconductor structure and the second semiconductor structure.

In some implementations, the first semiconductor structure includes a first local interconnect layer and is coupled to the interconnect layer through the first local interconnect layer.

In some implementations, the second semiconductor structure includes a second local interconnect layer and is coupled to the interconnect layer through the second local interconnect layer.

In some implementations, the first semiconductor structure is different from the second semiconductor structure.

In some implementations, the first semiconductor structure includes a logic die, the second semiconductor structure includes a memory die, and the first semiconductor structure and the second semiconductor structure are formed based on different levels of technology nodes.

In some implementations, the semiconductor device further includes a carrier structure bonded to the first semiconductor structure and the second semiconductor structure.

Another aspect of the present disclosure features a method. The method includes providing a first semiconductor structure including a first mark, a second semiconductor structure including a second mark, and a carrier structure including a third mark and a fourth mark. The method further includes stacking the first semiconductor structure at a first position on a surface of the carrier structure to align the first mark with the third mark along a direction perpendicular to the surface. The method further includes stacking the second semiconductor structure at a second position on the surface to align the second mark with the fourth mark along the direction. The method further includes bonding the first semiconductor structure and the second semiconductor structure to the carrier structure.

In some implementations, the first mark is different from the second mark, the first mark is the same as the third mark, and the second mark is the same as the fourth mark.

In some implementations, the first mark and the second mark include different numbers of a same pattern.

In some implementations, the method further includes forming an insulating structure over and surrounding the first semiconductor structure and the second semiconductor structure. The method further includes forming an interconnect layer over the insulating structure, where the first semiconductor structure and the second semiconductor structure are coupled through the interconnect layer.

In some implementations, the first mark includes a photoresist material.

In some implementations, the first mark includes openings on the surface of the first semiconductor structure. The method further includes forming the openings on the surface of the first semiconductor structure by an etching process.

In some implementations, the method further includes forming a redistribution layer over the interconnect layer.

In some implementations, the first semiconductor structure includes a logic die, the second semiconductor structure includes a memory die, and the carrier structure includes a carrier wafer.

In some implementations, the first semiconductor structure and the second semiconductor structure are formed based on different levels of technology nodes.

In some implementations, the method further includes forming the first mark in a first bonding layer of the first semiconductor structure, where the first mark includes a conductive material. The method further includes forming the second mark in a second bonding layer of the second semiconductor structure, where the second mark includes a conductive material. The method further includes forming the third mark and the fourth mark in a third bonding layer of the carrier structure, where the third mark and the fourth mark both include a conductive material.

### BRIEF DESCRIPTION OF DRAWINGS

FIGS. 1A-1I illustrate an example fabrication process for forming a semiconductor device.

FIG. 2 illustrates a flow chart of an example process 200 for forming a semiconductor device.

FIG. 3 illustrates a flow chart of an example process 300 for forming a semiconductor device.

Like reference numbers and designations in the various drawings indicate like elements.

### DETAILED DESCRIPTION

Packaging semiconductor chips or dies is a critical step in the semiconductor manufacturing process. The primary purpose of packaging is to protect the delicate semiconductor chips or dies and provide a means for them to connect to external devices or systems. In some cases, semiconductor chips or dies are stacked to achieve improved performance, reduced power consumption, and potentially reduced costs. Example methods of stacking semiconductor chips or dies can include wire bonding, though-silicon vias (TSVs), flip-chip stacking, package-on-package (POP), wafer-on-wafer stacking, chip-on-wafer-on-substrate (CoWoS) packages, etc. The choice of stacking method can depend on various factors including the intended application, costs, thermal considerations, and performance requirements.

Some conventional packaging methods require multiple semiconductor devices to be coupled to a substrate through conductive bumps. The conductive bumps (e.g., bumps having large pitches) may prevent more components to be integrated into a given space, thereby reducing a density of integrated circuits (ICs). For example, in CoWoS packages, multiple semiconductor devices can be disposed at different locations across a surface of an interposer. Each of the multiple semiconductor devices can be coupled to the interposer through conductive bumps. In some examples, the conductive bumps can be coupled to a front side of each semiconductor device. Due to large sizes of the conductive bumps, the number of connections (e.g., input/output (I/O) channels) between each semiconductor device and the interposer cannot be easily increased unless a size of the semiconductor device is increased to accommodate more conductive bumps. Furthermore, in some instances, coupling the multiple semiconductor devices to the interposer through the conductive bumps may require the multiple semiconductor devices to be manufactured using the most advanced technology node. Such a requirement may unnecessarily increase the manufacturing cost and reduce the production yield. Therefore, flexible semiconductor packaging methods that do not rely on conductive bumps and increase the integration density of IC chips are desired.

The present disclosure provides techniques for semiconductor packaging. In some implementations, multiple semiconductor devices are bonded to a carrier wafer. The multiple semiconductor devices can be disposed at different positions on a surface of the carrier wafer. The positions can be determined based on marks on each semiconductor device and on the carrier wafer. An interconnect layer can be formed over the multiple semiconductor devices. The interconnect layer can be coupled to connection lines of each semiconductor device through a back side of the semiconductor device.

Implementations of the present disclosure can provide one or more of the following technical advantages and/or benefits. An interconnect layer on a back side of multiple semiconductor devices, rather than conductive bumps on a front side of the multiple semiconductor devices, can be used to couple the multiple semiconductor devices. As such, the density of interconnections (e.g., I/O channels) between the multiple semiconductor devices can be increased, and a size of each semiconductor device can be decreased. The interconnect layer can be more reliable than the conductive bump that use solder. An interposer coupled to the multiple semiconductor devices may not be needed in a final package, thereby reducing manufacturing cost. Furthermore, the interconnect layer can include multiple layers of connection lines of different sizes. For example, a size (e.g., width and depth) of connection lines in a lower layer can be smaller than a size of connection lines in an upper layer. Thus, the multiple semiconductor devices can still be compatible with the interconnect layer even if they are formed based on different levels of technology nodes.

The techniques can be applied to various types of semiconductor devices, including but not limited to, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

The details of one or more implementations of the subject matter of this present disclosure are set forth in the accompanying drawings and the description below. Other features, aspects, and advantages of the subject matter will become apparent from the description, the drawings, and the claims.

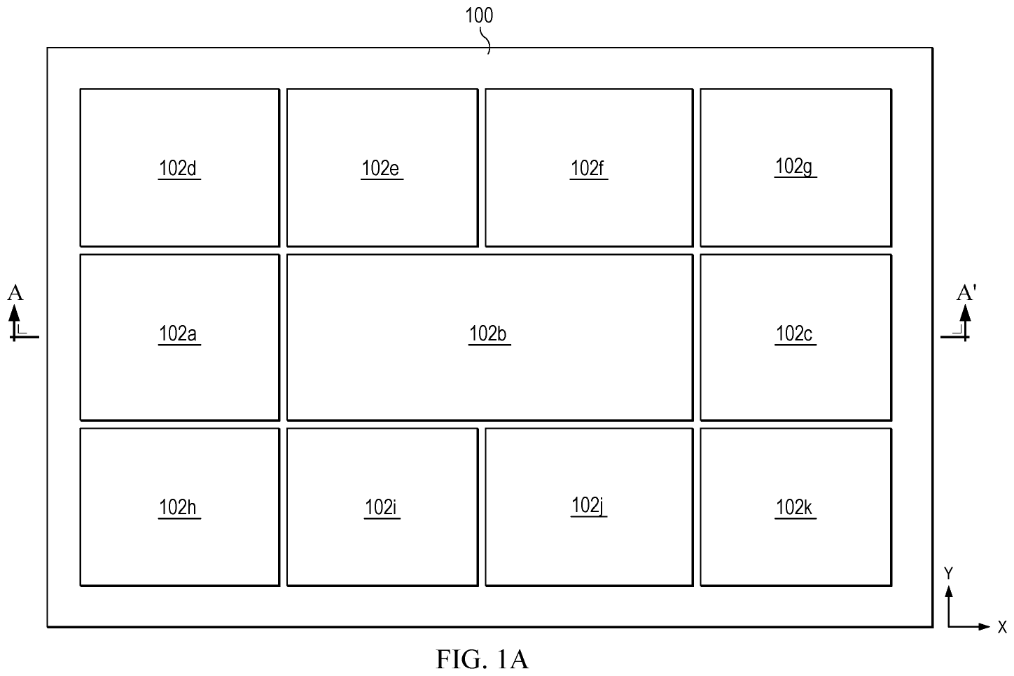

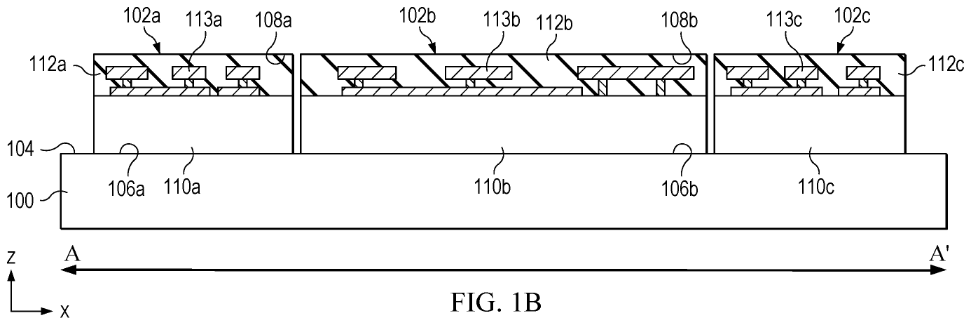

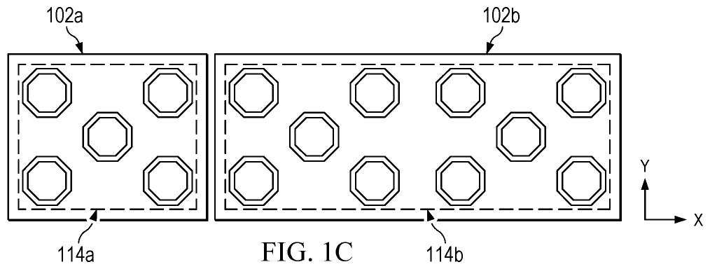

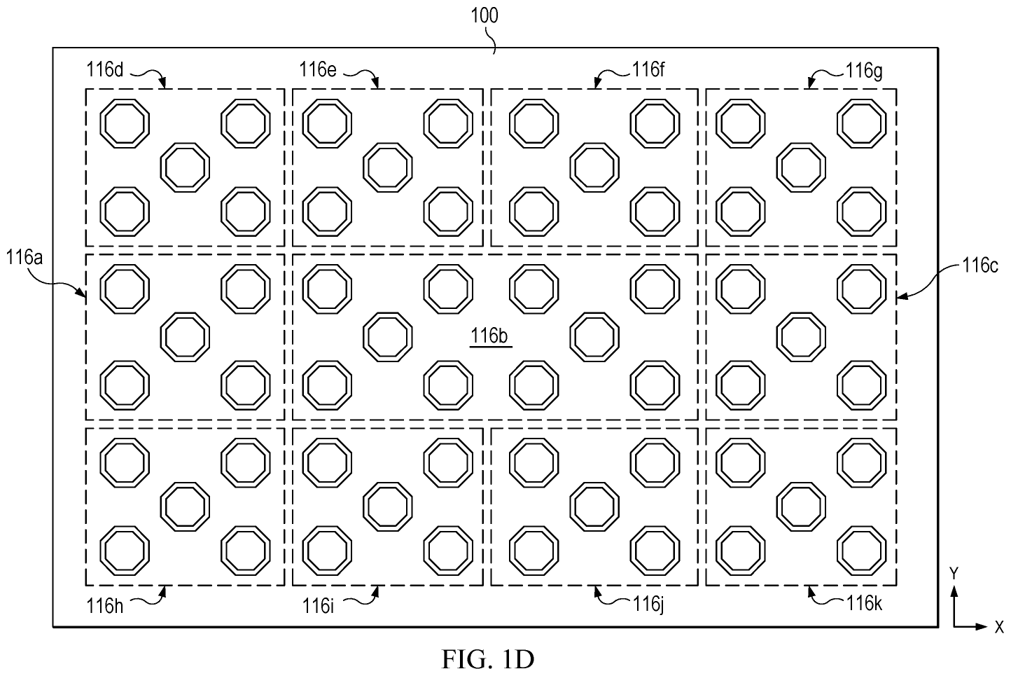

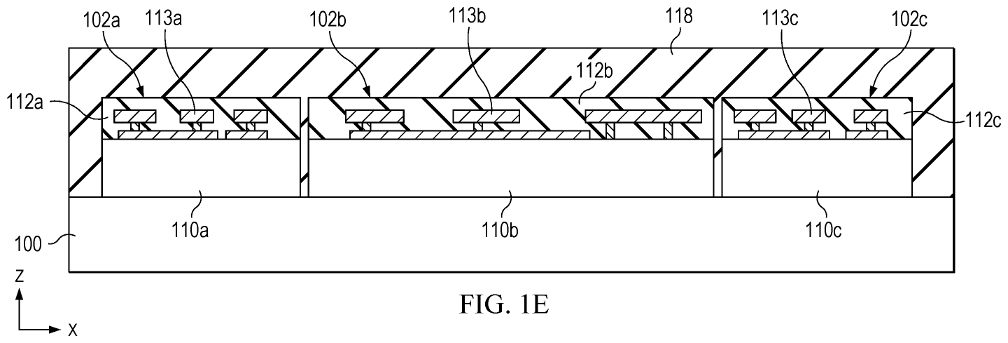

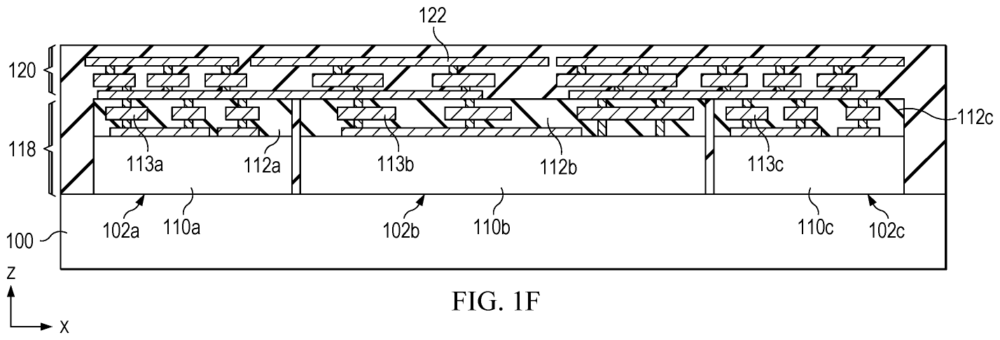

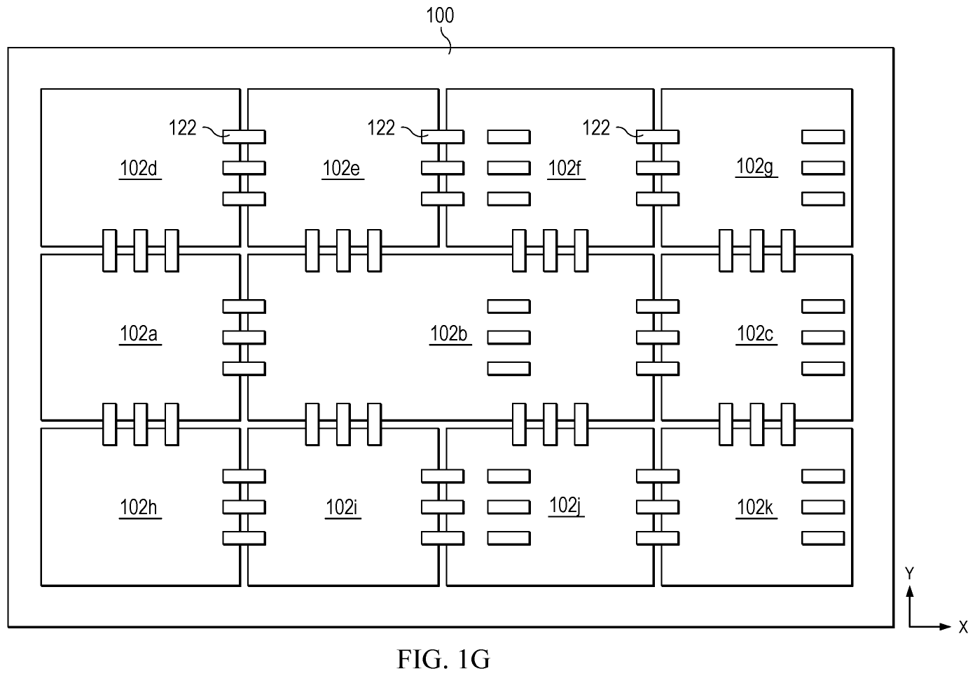

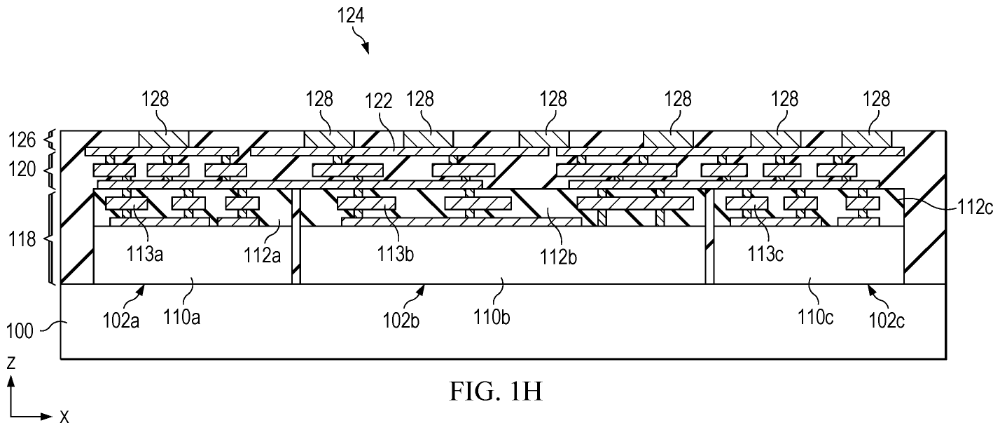

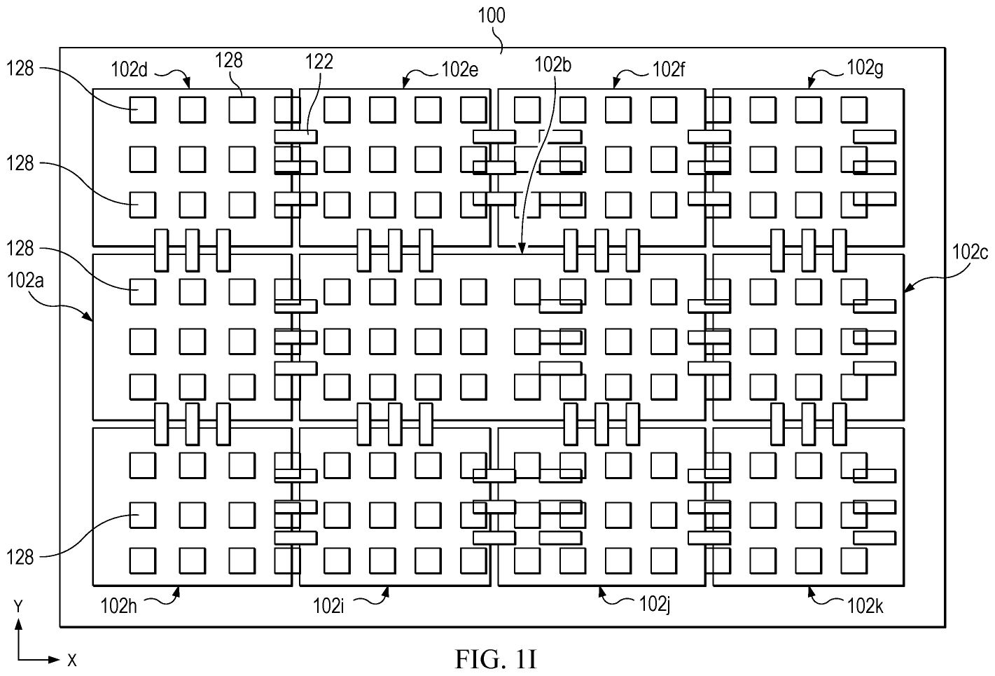

FIGS. 1A-1I illustrate an example fabrication process for forming a semiconductor device. In some implementations, the semiconductor device can be a bonded chip that includes multiple semiconductor structures.

It is noted that X, Y, and Z axes (also referred to as X, Y, and Z directions) are included in FIGS. 1A-1I to further illustrate the spatial relationship of various components in a semiconductor device. A substrate of the semiconductor device includes two lateral surfaces extending laterally in the X-Y plane: a top surface on the front side of a wafer on which a component of the semiconductor device can be formed, and a bottom surface on the backside opposite to the front side of the wafer. The Z direction is perpendicular to both the X and Y directions. As used herein, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

As shown in FIG. 1A, a carrier structure 100 and semiconductor structures 102a-102k are provided. In some implementations, carrier structure 100 can include a carrier wafer. For example, the carrier wafer can be a semiconductor substrate having any suitable semiconductor materials, such as monocrystalline, polycrystalline, or single crystalline semiconductors. It is understood that, in some implementations, the carrier wafer can include an insulating material (such as a dielectric) rather than a semiconductor material. In some implementations, the carrier wafer can include a combination of an insulating material and a semiconductor material. In some implementations, carrier structure 100 can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof.

Each of semiconductor structures 102a-102k can be a semiconductor structure including, but not limited to, a logic device, a memory device, a power management device, a central processing unit (CPU), a graphics processing unit (GPU), a neural processing unit (NPU), a digital signal processing (DSP) device, a modem device, a radio frequency device, an analog device, an audio/video encoding/decoding device, or any combination thereof. In some implementations, the bonded chip is a high bandwidth memory (HBM), and semiconductor structures 102a-102k can include a logic die and stacked memories of the high bandwidth memory. In some implementations, the bonded chip is a system on chip (SoC), and semiconductor structures 102a-102k can include a CPU, a GPU, a NPU, a DSP, a modem, and a random access memory (RAM) of the SoC. In some implementations, the bonded chip is a CPU or a GPU, and semiconductor structures 102a-102k can include various circuit modules of the CPU of the GPU.

In some implementations, each of semiconductor structures 102a-102k can be a die or multiple dies stacked together. Each of semiconductor structures 102a-102k can be manufactured by depositing multiple layers of various materials and etching them onto a semiconductor wafer in intricate patterns defined by a chip design. After the wafer fabrication process is complete, the wafer that includes individual circuits is cut and diced into individual pieces, each of which is a die. Each die includes a fully functional electronic circuit, which can be a microprocessor, memory, sensor, or any other suitable type of integrated circuit. In some embodiments, each die is encapsulated in a protective package, providing physical support, protection from environmental factor, and connections (e.g., through pins or solder balls) to external devices or system.

FIG. 1B illustrates a cross-sectional view of carrier structure 100 and semiconductor structures 102a-102c along cut line AA′ of FIG. 1A. It is understood that features of semiconductor structures 102a-102c described with respect to FIG. 1B are also applicable to other semiconductor structures (e.g., semiconductor structures 102d-102k). Each of semiconductor structures 102a-102c can be stacked on surface 104 of carrier structure 100 along a vertical direction (e.g., the Z direction). Surface 104 of carrier structure 100 extends laterally (e.g., in the X-Y plane). Semiconductor structures 102a-102c can be disposed at different positions on surface 104 (as shown in FIG. 1A). Each of semiconductor structures 102a-102c includes a surface (also referred to as a front surface or a bottom surface) closer to surface 104 and another surface (also referred to as a back surface or a top surface) further away from surface 104. For example, semiconductor structure 102a includes a front surface 106a and a back surface 108a, and semiconductor structure 102b includes a front surface 106b and a back surface 108b.

As shown in FIG. 1B, each of semiconductor structures 102a-102c can include a respective functional circuit (e.g., circuit 110a of semiconductor structure 102a, circuit 110b of semiconductor structure 102b, and circuit 110c of semiconductor structure 102c) and a respective interconnect layer (e.g., interconnect layer 112a of semiconductor structure 102a, interconnect layer 112b of semiconductor structure 102b, and interconnect layer 112c of semiconductor structure 102c) over the respective functional circuit. The respective interconnect layer in each of semiconductor structures 102a-102c can also be referred to as a local interconnect layer as it can transfer electrical signals between components within each of semiconductor structures 102a-102c.

Each local interconnect layer can include interconnects (also referred to herein as “contacts”), such as interconnects 113a in local interconnect layer 112a, interconnects 113b in local interconnect layer 112b, and interconnects 113c in local interconnect layer 112c, including lateral interconnect lines and vertical interconnect access (VIA) contacts. As used herein, the term “interconnects” can broadly include any suitable types of interconnects, such as middle-end-of-line (MEOL) interconnects and back-end-of-line (BEOL) interconnects. Each local interconnect layer can further include one or more interlayer dielectric (ILD) layers (also known as “intermetal dielectric (IMD) layers”) in which the interconnect lines and via contacts can form. That is, each local interconnect layer can include interconnect lines and via contacts in multiple ILD layers. The interconnects in each local interconnect layer can include conductive materials including, but not limited to, tungsten (W), cobalt (Co), copper (Cu), aluminum (Al), doped silicon, silicides, or any combination thereof. The ILD layers can be formed with dielectric materials including, but not limited to, silicon oxide, silicon nitride, silicon oxynitride, low-k dielectrics, or any combination thereof.

Semiconductor structures 102a-102k can be formed based on either different levels of technology nodes or the same level of technology node. In some implementations, if two semiconductor structure are formed based on two different levels of technology nodes, then sizes (e.g., width, depth, length) of interconnects in a local interconnect layer of one semiconductor structure can be different from sizes of interconnects in a local interconnect layer of another semiconductor structure.

In some implementations, semiconductor structure 102a can include a memory die, and semiconductor structure 102b can include a logic die. The logic die can include at least one processor that is configured to control the memory die. The memory die can include a memory device (e.g., a DRAM) or multiple memory devices (e.g., multiple stacked DRAMs) stacked along the Z direction.

Semiconductor structures 102a-102k can be bonded to carrier structure 100 by a bonding process. During the bonding process, each of semiconductor structures 102a-102k can be placed at a respective target position on surface 104 of carrier structure 100, and then can be bonded to surface 104. Any suitable bonding techniques can be applied to the bonding process. For example, semiconductor structures 102a-102k can be bonded to carrier structure 100 through an adhesive layer (not shown) disposed between semiconductor structures 102a-102k and surface 104. The adhesive layer can include any suitable types of adhesives. In some implementations, semiconductor structures 102a-102k can be bonded to carrier structure 100 using a direct bonding technology (e.g., forming bonding between surfaces without using intermediate layers, such as solder or adhesives). For example, each of semiconductor structures 102a-102k can include a dielectric layer on its front surface (e.g., front surfaces 106a and 106b). Carrier structure 100 can also include a dielectric layer on surface 104. The dielectric layers of semiconductor structures 102a-102k and the dielectric layer of carrier structure 100 can be formed of either the same dielectric material or different dielectric materials. The dielectric layers of semiconductor structures 102a-102k can be bonded to the dielectric layer of carrier structure 100 using the direct bonding technology (e.g., dielectric-dielectric bonding).

It is understood that semiconductor structures 102a-102k in figures in the present disclosure are for illustration purposes, and that in practice any suitable number of semiconductor structures can be bonded to carrier structure 100.

Carrier structure 100 and semiconductor structures 102a-102k can include marks to improve accuracy of positions of semiconductor structures 102a-102k on surface 104 during the bonding process. These marks can be referred to as bonding marks or alignment marks. In some implementations, each of semiconductor structures 102a-102k can include a respective mark. Carrier structure 100 can include multiple marks, and each of the multiple marks is associated with one of semiconductor structures 102a-102k.

FIG. 1C illustrates an example of a mark 114a of semiconductor structures 102a and a mark 114b of semiconductor structures 102b. FIG. 1D illustrates an example of marks 116a-116k of carrier structure 100. Mark 116a is associated with semiconductor structure 102a, and mark 116b is associated with semiconductor structure 102b. Similarly, marks 116c-116k can be associated with semiconductor structures 102c-102k, respectively. Each of semiconductor structures 102a-102k can have its mark formed either on its front surface, or on its back surface, or both, depending on specific setup and capability of a bonding system that performs the bonding process. Similarly, marks of carrier structure 100 also can be formed either on surface 104, or on another surface of carrier structure 100 opposite to surface 104, or both, depending on the setup and capability of the bonding system.

In some implementations, in the bonding process, a position (e.g., in the X-Y plane) of each semiconductor structure of semiconductor structures 102a-102k can be determined based on the semiconductor structure's mark and a mark on carrier structure 100 that is associated with the semiconductor structure. For example, mark 116a on carrier structure 100 can be the same as mark 114a on semiconductor structure 102a. The position of semiconductor structure 102a can be adjusted so that mark 116a is aligned with mark 114a along the Z direction.

In some implementations, the marks of semiconductor structures 102a-102k can be used for both alignment and identification of semiconductor structures 102a-102k. For example, semiconductor structures 102a-102k can have different marks, so that the bonding system can identify each of semiconductor structures 102a-102k based on their marks. In some implementations, each of semiconductor structures 102a-102k can have different numbers of a same pattern. This way, the bonding system can identify each semiconductor structure by counting the number of patterns the semiconductor structure has. As shown in FIG. 1C, for example, mark 114a of semiconductor structure 102a has 5 patterns. Each of the 5 patterns has the same shape, which is an octagon. Mark 114b of semiconductor structure 102b has 10 of the same patterns (the octagon shape). In some implementations, the semiconductor structures 102a-102k can have different patterns. The bonding system can identify and distinguish each semiconductor structure based on their patterns. The number of patterns that each of the semiconductor structures 102a-102k has is not limited. In other words, the semiconductor structures 102a-102k can have either the same number of patterns or different numbers of patterns, regardless of whether the patterns are the same.

In some implementations, the marks of semiconductor structures 102a-102k can be used for the alignment, and each of semiconductor structures 102a-102k can include a separate label for the identification purpose.

The marks of semiconductor structures 102a-102k and carrier structure 100 can be formed using any suitable techniques. In some implementations, the marks can be photoresist masks formed by a lithography process. In some implementations, the marks can be grooves or openings formed on the surfaces of semiconductor structures 102a-102k and carrier structure 100 by an etching process. The grooves or openings may not be filled with any filling material. In some implementations, the marks can include a dielectric material (e.g., silicon oxide) or a conductive material (e.g., metal) filled in the grooves or openings.

In some implementations, the marks of semiconductor structures 102a-102k and carrier structure 100 can be used for bonding. Each of semiconductor structures 102a-102k can include a respective bonding layer on its front surface (e.g., surfaces 106a and 106b of FIG. 1B). Each respective bonding layer can include a mark (e.g., mark 114a for semiconductor structure 102a and mark 114b for semiconductor structure 102b of FIG. 1C) formed of conductive materials (e.g., metal) and a dielectric material surrounding the mark. Carrier structure 100 can include a bonding layer on surface 104. The bonding layer of carrier structure 100 can also include marks (e.g., marks 116a-116k of FIG. 1D) formed of conductive materials (e.g., metal) and a dielectric material surrounding the marks. In the bonding process, each of semiconductor structures 102a-102k can be bonded to carrier structure 100 through a hybrid dielectric-dielectric and metal-metal bonding technology. For example, mark 114a of semiconductor structure 102a is bonded to mark 116a of carrier structure 100 through metal-metal bonding, and mark 114b of semiconductor structure 102b is bonded to mark 116b of carrier structure 100 through metal-metal bonding. The dielectric material surrounding mark 114a in the bonding layer of semiconductor structure 102a is bonded to the dielectric material surrounding mark 116a in the bonding layer of carrier structure 100 through dielectric-dielectric bonding. The dielectric material surrounding mark 114b in the bonding layer of semiconductor structure 102b is bonded to the dielectric material surrounding mark 116b in the bonding layer of carrier structure 100 through dielectric-dielectric bonding.

It is understood that the above-mentioned examples are for illustration purpose and that in practice any suitable mark designs can be used to form the marks of semiconductor structures 102a-102k and carrier structure 100.

As shown in FIG. 1E, an insulating structure 118 is formed over and surrounding semiconductor structures 102a-102k. Insulating structure 118 can be formed by filling an insulating material into the space between and over semiconductor structures 102a-102k. The insulating material can include any suitable dielectric materials including, but not limited to, silicon oxide, silicon nitride, silicon oxynitride, or any combination thereof. In some implementations, a planarization process, such as chemical mechanical polishing (CMP), can then be performed to polish a top surface of insulating structure 118.

In some implementations, other semiconductor structures (not shown) that are similar to or the same as semiconductor structures 102a-102k can be stacked on and bonded to carrier structure 100 (e.g., the carrier wafer). The filling process can also fill the space between the other semiconductor structures and semiconductor structures 102a-102k, thereby forming a new wafer that is stacked on the carrier wafer 100. The new wafer can be referred to as a device wafer. The device wafer can include the other semiconductor structures, semiconductor structures 102a-102k, and insulating structure 118 that is over and surrounding the other semiconductor structures and semiconductor structures 102a-102k. The device wafer can include scribe lines that separate semiconductor structures 102a-102k from the other semiconductor structures. The subsequence processes as shown in FIGS. 1F-1I can be performed at the wafer level on the device wafer and the carrier wafer 100. After these subsequence processes are completed, the bonded chip that includes semiconductor structures 102a-102k can be cut apart from the device wafer along the scribe lines.

As shown in FIG. 1F, an interconnect layer 120 can be formed over semiconductor structures 102a-102k and insulating structure 118. Interconnect layer 120 can provide connections between semiconductor structures 102a-102k. In some implementations, interconnect layer 120 can include interconnects 122 (also referred to herein as “contacts”), including lateral interconnect lines and VIA contacts. Interconnects 122 can be coupled to interconnects (e.g., interconnects 113a, 113b, and 113c) in a respective local interconnect layer (e.g., local interconnect layers 112a, 112b, and 112c) of each of semiconductor structures 102a-102k. In some implementations, insulating structure 118 can be thinned to expose the local interconnect layer of semiconductor structures 102a-102k before forming interconnect layer 120. Interconnect layer 120 can further include one or more ILD layers (also known as IMD layers) in which the interconnect lines and via contacts can form. That is, interconnect layer 120 can include interconnect lines and via contacts in multiple ILD layers. The interconnects in interconnect layer 120 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

In some implementations, semiconductor structures 102a-102k can be formed based on different levels of technology nodes. For example, semiconductor structure 102a can be formed with a technology node of 28 nm, and semiconductor structure 102b can be formed with a technology node of 10 nm. As such, sizes of interconnects 113a in local interconnect layer 112a of semiconductor structure 102a can be much larger than sizes of interconnects 113b in local interconnect layer 112b of semiconductor structure 102b. Due to the size differences, it may be challenging to form interconnects in interconnect layer 120 that directly connect interconnects 113a and interconnects 113b. To address this issue, interconnect layer 120 can include multiple ILD layers over semiconductor structure 102b that are coupled to interconnects 113b in local interconnect layer 112b. A lower ILD layer (e.g., an ILD layer that is closer to carrier structure 100 along the Z direction) of the multiple ILD layers can be formed prior to an upper ILD layer (e.g., an ILD layer that is further away from carrier structure 100 along the Z direction) of the multiple ILD layers. Sizes of interconnects in the upper ILD layer can be greater than sizes of interconnects in the lower ILD layer. Thus, sizes of interconnects in the topmost ILD layer of the multiple ILD layers over semiconductor structure 102b can be similar to or the same as sizes of interconnects over semiconductor structure 102a that are coupled to interconnects 113a in local interconnect layer 112a. Therefore, the multiple ILD layers in the interconnect layer 120 can make it easier to from conductive lines that connect the interconnects of different sizes in the local interconnect layers.

FIG. 1G illustrates a top view of example interconnects 122 in interconnect layer 120. In practice, interconnects 122 can provide connections between any of semiconductor structures 102a-102k including, but not limited to, adjacent semiconductor structures of semiconductor structures 102a-102k (as shown in FIG. 1G).

FIG. 1H illustrates a cross-sectional view of a semiconductor device 124. Semiconductor device 124 can be an example of the bonded chip. As shown in FIG. 1H, semiconductor device 124 can include carrier structure 100, semiconductor structures 102a-102k, insulating structure 118, interconnect layer 120, and a redistribution layer 126. Redistribution layer 126 can be formed on top of interconnect layer 120 for pad-out (e.g., transferring electrical signals between interconnect layer 120 and external circuits). In some implementations, as shown in FIG. 1H, redistribution layer 126 can include conductive pads 128 that are coupled to interconnects 122 of interconnect layer 120 and are exposed from redistribution layer 126.

FIG. 1I illustrates a top view of semiconductor device 124. While FIG. 1I shows that cross sections of conductive pads 128 in the top view can have a square shape, it is understood that in practice, the cross sections of conductive pads 128 can also have a rectangular shape, a trapezoidal shape, a circular shape, an oval shape, or any other suitable shapes.

In some implementations, carrier structure 100 can be thinned or removed from semiconductor device 124, thereby reducing a size of semiconductor device 124. For example, carrier structure 100 can be separated from semiconductor device 124 by a de-bonding process and can be re-used in fabrication of other semiconductor structures. In another example, carrier structure 100 can be thinned or removed by a planarization process (e.g., CMP).

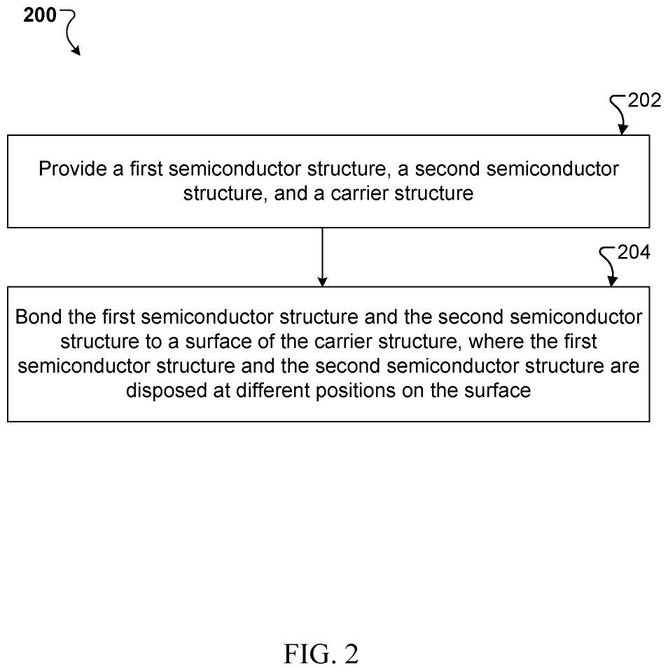

FIG. 2 illustrates a flow chart of an example process 200 for forming a semiconductor device. For example, the semiconductor device can be similar to, or the same as, semiconductor device 124 of FIG. 1H. The process 200 can be described in view of FIGS. 1A-1I. The process 200 can include the fabrication process of forming semiconductor structures in FIGS. 1A-1I. It is understood that the operations shown in process 200 are not exhaustive and that other operations can be performed as well before, after, or between any of the illustrated operations. Further, some of the operations may be performed simultaneously, or in a different order than shown in FIG. 2.

At operation 202, a first semiconductor structure (e.g., semiconductor structure 102a of FIG. 1A), a second semiconductor structure (e.g., semiconductor structure 102b of FIG. 1A), and a carrier structure (e.g., carrier structure 100 of FIG. 1A) are provided. In some implementations, the first semiconductor structure is different from the second semiconductor structure. In some implementations, the first semiconductor structure includes a logic die, the second semiconductor structure includes a memory die, and the carrier structure includes a carrier wafer. In some implementations, the first semiconductor structure and the second semiconductor structure are formed based on different levels of technology nodes.

At operation 204, the first semiconductor structure and the second semiconductor structure are bonded to a surface (e.g., surface 104 of FIG. 1B) of the carrier structure. In some implementations, the first semiconductor structure and the second semiconductor structure are disposed at different positions on the surface.

In some implementations, a first mark (e.g., mark 114a of FIG. 1C) can be formed on a surface (e.g., surface 106a of FIG. 1B) of the first semiconductor structure, a second mark (e.g., mark 114b of FIG. 1C) can be formed on a surface (e.g., surface 106b of FIG. 1B) of the second semiconductor structure, and a third mark (e.g., mark 116a of FIG. 1D) and a fourth mark (e.g., mark 116b of FIG. 1D) can be formed on the surface (e.g., surface 104) of the carrier structure. In some implementations, a first position of the first semiconductor structure on the surface is determined based on the first mark and the third mark, and a second position of the second semiconductor structure on the surface is determined based on the second mark and the fourth mark.

In some implementations, an insulating structure (e.g., insulating structure 118 of FIG. 1E) is formed over and surrounding the first semiconductor structure and the second semiconductor structure.

In some implementations, an interconnect layer (e.g., interconnect layer 120 of FIG. 1F) is formed over the insulating structure. In some implementations, the first semiconductor structure and the second semiconductor structure are coupled through the interconnect layer. In some implementations, a redistribution layer (e.g., redistribution layer 126 of FIG. 1H) can be formed over the interconnect layer.

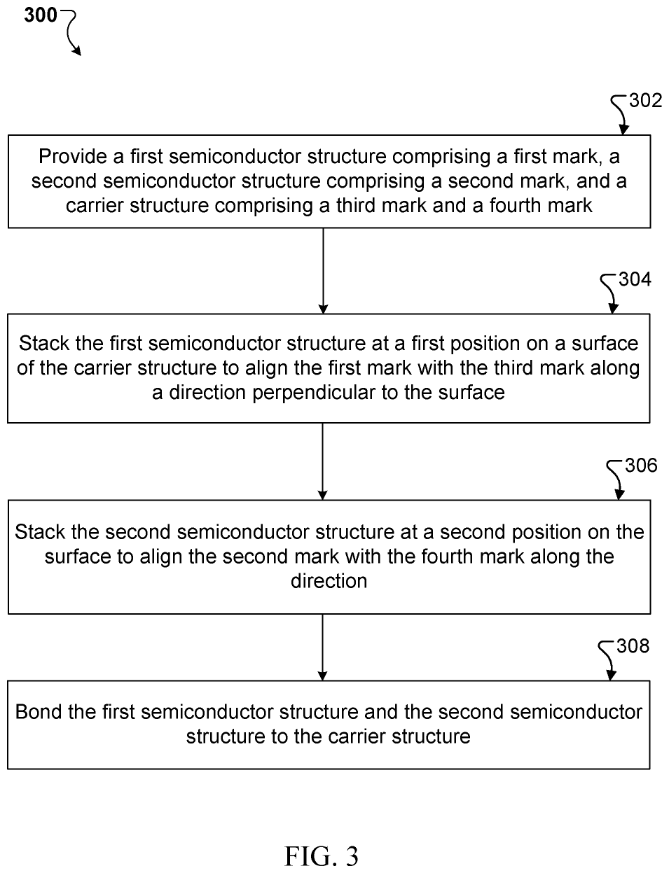

FIG. 3 illustrates a flow chart of an example process 300 for forming a semiconductor device. For example, the semiconductor device can be similar to, or the same as, semiconductor device 124 of FIG. 1H. The process 300 can be described in view of FIGS. 1A-1I. The process 300 can include the fabrication process of forming semiconductor structures in FIGS. 1A-1I. It is understood that the operations shown in process 300 are not exhaustive and that other operations can be performed as well before, after, or between any of the illustrated operations. Further, some of the operations may be performed simultaneously, or in a different order than shown in FIG. 3.

At operation 302, a first semiconductor structure (e.g., semiconductor structure 102a of FIG. 1A) including a first mark (e.g., mark 114a of FIG. 1C), a second semiconductor structure (e.g., semiconductor structure 102b of FIG. 1A) including a second mark (e.g., mark 114b of FIG. 1C), and a carrier structure (e.g., carrier structure 100 of FIG. 1A) including a third mark (e.g., mark 116a of FIG. 1D) and a fourth mark (e.g., mark 116b of FIG. 1D) are provided.

In some implementations, the first semiconductor structure is different from the second semiconductor structure. In some implementations, the first semiconductor structure includes a logic die, the second semiconductor structure includes a memory die, and the carrier structure includes a carrier wafer. In some implementations, the first semiconductor structure and the second semiconductor structure are formed based on different levels of technology nodes.

At operation 304, the first semiconductor structure is stacked at a first position on a surface (e.g., surface 104) of the carrier structure to align the first mark with the third mark along a direction (e.g., the vertical direction) perpendicular to the surface.

In some implementations, the first mark (e.g., mark 114a of FIG. 1C) can be formed on a surface (e.g., surface 106a of FIG. 1B) of the first semiconductor structure, the second mark (e.g., mark 114b of FIG. 1C) can be formed on a surface (e.g., surface 106b of FIG. 1B) of the second semiconductor structure, and the third mark (e.g., mark 116a of FIG. 1D) and the fourth mark (e.g., mark 116b of FIG. 1D) can be formed on the surface (e.g., surface 104) of the carrier structure.

At operation 306, the second semiconductor structure is stacked at a second position on the surface to align the second mark with the fourth mark along the direction.

At operation 308, the first semiconductor structure and the second semiconductor structure are bonded to the carrier structure.

In some implementations, an insulating structure (e.g., insulating structure 118 of FIG. 1E) is formed over and surrounding the first semiconductor structure and the second semiconductor structure.

In some implementations, an interconnect layer (e.g., interconnect layer 120 of FIG. 1F) is formed over the insulating structure. The first semiconductor structure and the second semiconductor structure are coupled through the interconnect layer. In some implementations, a redistribution layer (e.g., redistribution layer 126 of FIG. 1H) can be formed over the interconnect layer.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A method, comprising:
providing a first semiconductor structure, a second semiconductor structure, and a carrier structure; and
bonding the first semiconductor structure and the second semiconductor structure to a surface of the carrier structure, wherein the first semiconductor structure and the second semiconductor structure are disposed at different positions on the surface.

2. The method according to claim 1, further comprising:
forming a redistribution layer.

3. The method according to claim 1, wherein the first semiconductor structure is different from the second semiconductor structure.

4. The method according to claim 3, wherein:
the first semiconductor structure comprises a logic die;
the second semiconductor structure comprises a memory die; and
the carrier structure comprises a carrier wafer.

5. The method according to claim 1, further comprising:
forming a first mark on a surface of the first semiconductor structure;
forming a second mark on a surface of the second semiconductor structure; and
forming a third mark and a fourth mark on the surface of the carrier structure, wherein:
a first position of the first semiconductor structure on the surface is determined based on the first mark and the third mark; and
a second position of the second semiconductor structure on the surface is determined based on the second mark and the fourth mark.

6. The method according to claim 1, wherein the first semiconductor structure and the second semiconductor structure are formed based on different levels of technology nodes, and wherein the method further comprises:
forming an insulating structure over and surrounding the first semiconductor structure and the second semiconductor structure; and
forming an interconnect layer over the insulating structure, wherein the first semiconductor structure and the second semiconductor structure are coupled through the interconnect layer.

7. A semiconductor device, comprising:
a first semiconductor structure and a second semiconductor structure disposed at different positions on a surface;
an interconnect layer over the first semiconductor structure and the second semiconductor structure, wherein the first semiconductor structure and the second semiconductor structure are coupled through the interconnect layer; and
a redistribution layer over the interconnect layer, wherein the redistribution layer is coupled to the interconnect layer.

8. The semiconductor device according to claim 7, wherein the redistribution layer comprises a conductive pad coupled to the interconnect layer.

9. The semiconductor device according to claim 7, further comprising:
an insulating structure isolating the first semiconductor structure and the second semiconductor structure.

10. The semiconductor device according to claim 7, wherein:
the first semiconductor structure comprises a first local interconnect layer and is coupled to the interconnect layer through the first local interconnect layer.

11. The semiconductor device according to claim 10, wherein the second semiconductor structure comprises a second local interconnect layer and is coupled to the interconnect layer through the second local interconnect layer.

12. The semiconductor device according to claim 7, wherein the first semiconductor structure is different from the second semiconductor structure.

13. The semiconductor device according to claim 12, wherein:
the first semiconductor structure comprises a logic die;
the second semiconductor structure comprises a memory die; and
the first semiconductor structure and the second semiconductor structure are formed based on different levels of technology nodes.

14. The semiconductor device according to claim 7, further comprising:
a carrier structure bonded to the first semiconductor structure and the second semiconductor structure.

15. A method, comprising:
providing a first semiconductor structure comprising a first mark, a second semiconductor structure comprising a second mark, and a carrier structure comprising a third mark and a fourth mark;
stacking the first semiconductor structure at a first position on a surface of the carrier structure to align the first mark with the third mark along a direction perpendicular to the surface;
stacking the second semiconductor structure at a second position on the surface to align the second mark with the fourth mark along the direction; and
bonding the first semiconductor structure and the second semiconductor structure to the carrier structure.

16. The method according to claim 15, wherein:
the first mark is different from the second mark;
the first mark is the same as the third mark; and
the second mark is the same as the fourth mark.

17. The method according to claim 16, further comprising:
forming an insulating structure over and surrounding the first semiconductor structure and the second semiconductor structure; and
forming an interconnect layer over the insulating structure, wherein the first semiconductor structure and the second semiconductor structure are coupled through the interconnect layer.

18. The method according to claim 15, wherein the first mark comprises a photoresist material.

19. The method according to claim 15, wherein the first mark comprises openings on the surface of the first semiconductor structure, and wherein the method further comprises:
forming the openings on the surface of the first semiconductor structure by an etching process.

20. The method according to claim 15, further comprising:
forming the first mark in a first bonding layer of the first semiconductor structure, wherein the first mark comprises a conductive material;
forming the second mark in a second bonding layer of the second semiconductor structure, wherein the second mark comprises a conductive material; and
forming the third mark and the fourth mark in a third bonding layer of the carrier structure, wherein the third mark and the fourth mark both comprise a conductive material.
